(19) United States
(12) Patent Application Publication
(10) Pub. No.: US 2022/0299554 A1
(43) Pub. Date: Sep. 22, 2022

(54) APPARATUS FOR ELECTROSTATIC DISCHARGE TEST

(71) Applicant: ELECTRONICS AND TELECOMMUNICATIONS RESEARCH INSTITUTE, Daejeon (KR)

(72) Inventors: Dong Yun JUNG, Daejeon (KR); Hyun Gyu JANG, Daejeon (KR); Kun Sik PARK, Daejeon (KR); JONG IL WON, Daejeon (KR); Sung Kyu KWON, Daejeon (KR); Jong Won LIM, Daejeon (KR); Doo Hyung CHO, Daejeon (KR)

(73) Assignee: ELECTRONICS AND TELECOMMUNICATIONS RESEARCH INSTITUTE, Daejeon (KR)

(21) Appl. No.: 17/510,856

(22) Filed: Oct. 26, 2021

(30) Foreign Application Priority Data
Mar. 19, 2021 (KR) 10-2021-0035985
Oct. 6, 2021 (KR) 10-2021-0132405

(51) Int. Cl. G01R 31/00

(52) U.S. Cl. CPC G01R 31/002; G01R 31/2642

(57) ABSTRACT

The apparatus for ESD test includes a micro-controller unit client, a low voltage supply configured to output a low voltage on the basis of control by the micro-controller unit, a high voltage supply configured to output a high voltage on the basis of control by the micro-controller unit, and an ESD generator configured to generate an ESD voltage for an ESD test of a device under test (DUT) by using the low voltage and the high voltage, on the basis of control by the micro-controller unit. The ESD generator is a semiconductor integrated circuit module where a charging semiconductor switch, a discharging semiconductor switch, a switch driving block controlling a switching operation of each of the charging semiconductor switch and the discharging semiconductor switch, and a plurality of passive elements connected to the charging semiconductor switch and the discharging semiconductor switch are implemented as package, for generating the ESD voltage.

### CROSS-REFERENCE TO RELATED APPLICATIONS

This application claims priority under 35 U.S.C. § 119 to Korean Patent Application Nos. 10-2021-0035985, filed on Mar. 19, 2021, and 10-2021-0132405, filed on Oct. 6, 2021, the disclosure of which is incorporated herein by reference in its entirety.

### TECHNICAL FIELD

The present invention relates to an apparatus for testing the reliability or immunity of electrostatic discharge (ESD) of a semiconductor or electronic/electrical device.

### BACKGROUND

An ESD test is an essential item for verifying the stability of an electronic/electrical device. A test apparatus for instantaneously discharging a high voltage is necessarily needed for ESD test.

FIG. 1 is a circuit diagram of a general ESD generator.

Referring to FIG. 1, the general ESD generator includes a high voltage (HV) supply 10, a device under test (DUT) 20, a plurality of relay switches 30 and 40, and a plurality of passive elements R1, R2, and C1.

A voltage output from the high voltage supply 10 is charged into a capacitor Cl via a charging resistor R1 on the basis of a switching operation of the relay switch 30, and a voltage charged into the capacitor C1 is discharged to the DUT 20 via a discharging resistor R2 on the basis of a switching operation of the relay switch 40.

FIG. 2 is a waveform diagram showing an output current waveform of an ESD generator defined based on IEC61000-4-2 standard for evaluating ESD of a finished product (for example, finished electronic/electrical products such as smartphones and televisions (TVs)), and FIG. 3 is a waveform diagram showing an output current waveform of an ESD generator defined based on MIL-STD 883E (HBM) standard for evaluating the immunity of ESD in a process of manufacturing a product (for example, a semiconductor product such as a semiconductor wafer).

The ESD generator for testing ESD on the basis of IEC61000-4-2 standard and the ESD generator for testing ESD on the basis of MIL-STD 883E (HBM) standard are each configured with the same circuit as a circuit illustrated in FIG. 1.

However, due to a difference between the output current waveform of FIG. 2 defined based on IEC61000-4-2 standard and the output current waveform of FIG. 3 defined based on MIL-STD 883E (HBM) standard, the passive elements R1, R2, and C1 of the ESD generators based on two standards have a difference in that the ESD generators have different resistance values and capacitances.

The following Table 1 shows a supply voltage defined based on each standard and a peak current corresponding thereto.

TABLE 1

| | Peak Current [A] | |
|---|---|---|
| Supply Voltage [V] | MIL-STD 883E (HBM) | IEC61000-4-2 |
| 500 | 0.33 | — |
| 1,000 | 0.67 | — |
| 2,000 | 1.33 | 7.5 |
| 4,000 | 2.67 | 15.0 |
| 6,000 | 4.00 | 22.5 |
| 8,000 | 5.33 | 30.0 |
| 10,000 | 6.67 | 37.5 |

As seen in Table 1, an ESD generator should satisfy excellent current slope (di/dt) performance so that a very high peak current is generated for a short time for an appropriate ESD test.

In order to provide excellent current slope performance, a chattering phenomenon should not occur in a general ESD generator when a supply voltage is applied thereto, and a mercury relay having a high operation speed is being widely used. Despite such advantages, the mercury relay has problems such as environmental pollution and a reduction in performance caused by mercury evaporation when the mercury relay maintains an operation standby state for a long time.

### SUMMARY

Accordingly, the present invention provides an apparatus for ESD test, which has an excellent current slope characteristic without designing of a mercury relay, in order to test the reliability or immunity of ESD in a process of manufacturing a finished product or a product.

In one general aspect, an apparatus for electrostatic discharge (ESD) test includes: a micro-controller unit client; a low voltage supply configured to output a low voltage on the basis of control by the micro-controller unit; a high voltage supply configured to output a high voltage on the basis of control by the micro-controller unit; and an ESD generator configured to generate an ESD voltage for an ESD test of a device under test (DUT) by using the low voltage and the high voltage, on the basis of control by the micro-controller unit, wherein the ESD generator is a semiconductor integrated circuit module where a charging semiconductor switch, a discharging semiconductor switch, a switch driving block controlling a switching operation of each of the charging semiconductor switch and the discharging semiconductor switch, and a plurality of passive elements connected to the charging semiconductor switch and the discharging semiconductor switch are implemented as package, for generating the ESD voltage.

In an embodiment, each of the charging semiconductor switch and the discharging semiconductor switch may be a semiconductor switch replacing a mercury relay switch included in a conventional ESD generator.

In an embodiment, each of the charging semiconductor switch and the discharging semiconductor switch may be one of a thyristor-based semiconductor device including a MOS controlled (MCT) thyristor, a field effect transistor (FET)-based semiconductor device, an insulated gate bipolar transistor (IGBT)-based semiconductor device, and a bipolar junction transistor (BJT)-based semiconductor device.

In an embodiment, the switch driving block may output a first switching driving voltage for controlling a switching operation of the charging semiconductor switch and a second switching driving voltage for controlling a switching operation of the discharging semiconductor switch, by using the low voltage.

In an embodiment, the switch driving block may include: a voltage converter configured to boost or drop the low voltage; a charging switching driver configured to output the first switching driving voltage corresponding to the boosted or dropped low voltage on the basis of control by the micro-controller unit; a discharging switching driver configured to output the second switching driving voltage corresponding to the low voltage on the basis of control by the micro-controller unit.

In an embodiment, the first and second switching driving voltages may have the same voltage level as a voltage level of the low voltage.

In an embodiment, the switch driving block may include: a voltage converter configured to boost or drop the low voltage; and a charging switching driver configured to output the first switching driving voltage corresponding to the boosted or dropped low voltage on the basis of control by the micro-controller unit, and the discharging semiconductor switch performs a switching operation on the basis of the second switching driving voltage output from the micro-controller unit.

In an embodiment, the apparatus for ESD test may further include: a first voltage converter configured to boost or drop the low voltage; a charging switching driver configured to output the first switching driving voltage corresponding to a low voltage boosted or dropped by the first voltage converter on the basis of control by the micro-controller unit; a second voltage converter configured to boost or drop the low voltage; and a discharging switching driver configured to output the second switching driving voltage corresponding to a low voltage boosted or dropped by the second voltage converter on the basis of control by the micro-controller unit.

In an embodiment, the first and second switching driving voltages have a voltage level which differs from a voltage level of the low voltage.

In an embodiment, the plurality of passive elements may include: a charging resistor including one terminal connected to a drain terminal of the charging semiconductor switch and the other terminal connected to a positive terminal of the high voltage supply; a charging/discharging capacitor including one electrode connected to a source terminal of the charging semiconductor switch and the other electrode connected to a negative terminal of the high voltage supply; and a discharging resistor connecting a source terminal of the charging semiconductor switch to a drain terminal of the discharging semiconductor switch.

In an embodiment, when a first node connecting a ground to the other electrode of the charging/discharging capacitor and the negative terminal of the high voltage supply and a second node connecting the first node to the ground are defined, a high voltage output from the high voltage supply may be charged into the charging/discharging capacitor via the charging resistor and the turned-on charging semiconductor switch, and a charging voltage charged into the charging/discharging capacitor may be output as the ESD voltage via the discharging resistor and the turned-on discharging semiconductor switch.

In an embodiment, the charging semiconductor switch and the discharging semiconductor switch may have a breakdown voltage characteristic which is higher than the charging voltage.

In another general aspect, an apparatus for electrostatic discharge (ESD) test includes: a charging pulse transformer driver configured to convert a low voltage to generate a first switching driving voltage; a discharging pulse transformer driver configured to convert the low voltage to generate a second switching driving voltage; a charging semiconductor switch configured to perform a switching operation on the basis of the first switching driving voltage; a discharging semiconductor switch configured to perform a switching operation on the basis of the second switching driving voltage; and a capacitor configured to store a high voltage on the basis of a switching operation of the charging semiconductor switch and to output the stored high voltage as an ESD voltage for an ESD test of a device under test (DUT) on the basis of a switching operation of the discharging semiconductor switch.

In an embodiment, the charging pulse transformer driver, the discharging pulse transformer driver, the charging semiconductor switch, and the discharging semiconductor switch may be packaged by one semiconductor integrated circuit module.

In an embodiment, each of the charging pulse transformer driver and the discharging pulse transformer driver may include: a pulse generating circuit configured to generate a pulse voltage corresponding to the low voltage; and a transformer including a primary coil configured to convert the pulse voltage to generate a switching driving voltage and a secondary coil electromagnetically coupled to the primary coil.

In an embodiment, a turn ratio between the primary coil and the secondary coil may be determined based on a ratio of the low voltage to the switching driving voltage.

Other features and aspects will be apparent from the following detailed description, the drawings, and the claims.

### BRIEF DESCRIPTION OF THE DRAWINGS

FIG. 1 is a circuit diagram of a general ESD generator.

FIG. 2 is a waveform diagram showing an output current waveform of an ESD generator defined based on IEC61000-4-2 standard for evaluating ESD of a finished product (for example, finished electronic/electrical products such as smartphones and televisions (TVs)).

FIG. 3 is a waveform diagram showing an output current waveform of an ESD generator defined based on MIL-STD 883E (HBM) standard for evaluating the immunity of ESD in a process of manufacturing a product (for example, a semiconductor product such as a semiconductor wafer).

FIG. 4 is a block diagram of an apparatus for ESD test according to an embodiment of the present invention.

FIG. 5 is a block diagram illustrating an example of a switch driving block illustrated in FIG. 4.

FIG. 6 is a block diagram illustrating another example of the switch driving block illustrated in FIG. 4.

FIG. 7 is a block diagram illustrating another example of the switch driving block illustrated in FIG. 4.

FIG. 8 is a block diagram illustrating an example of a pulse transformer driver illustrated in FIG. 7.

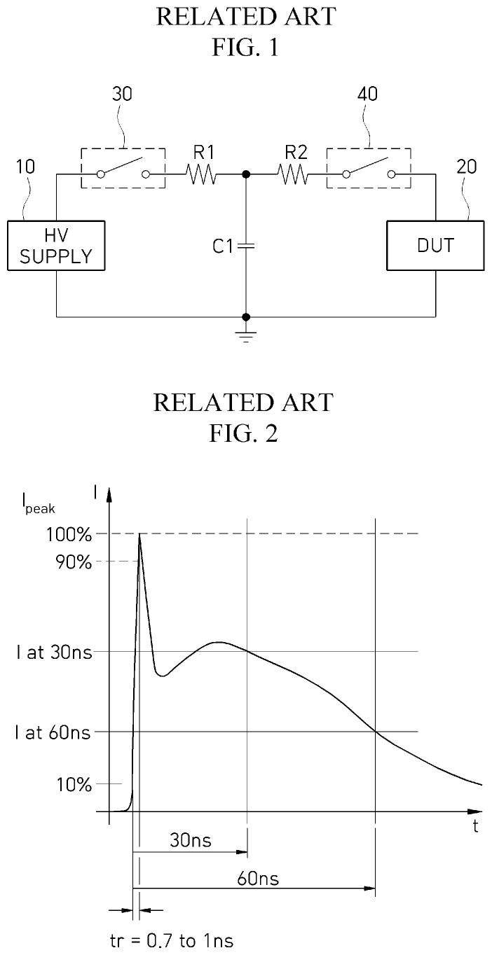

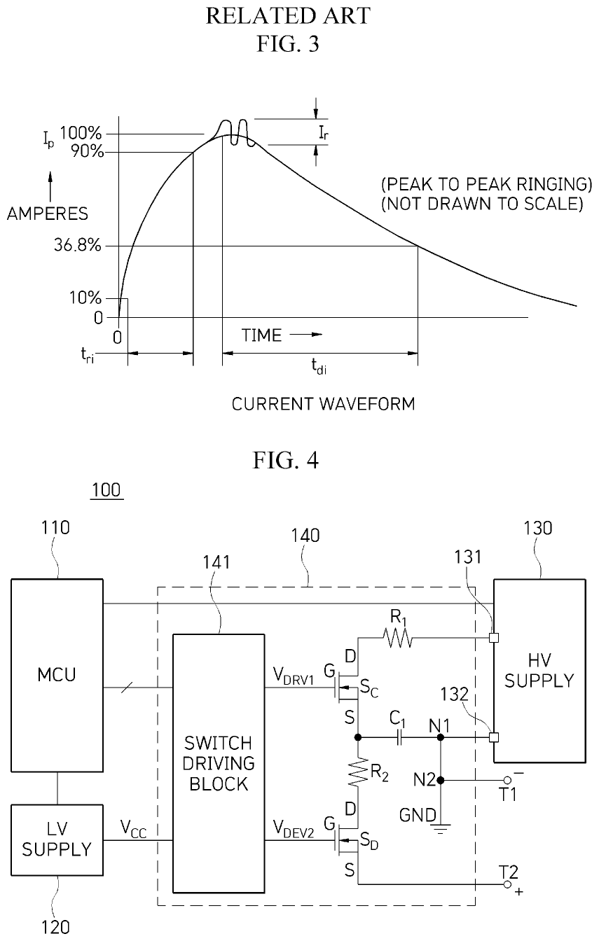

### DETAILED DESCRIPTION OF EMBODIMENTS

In embodiments of the present invention disclosed in the detailed description, specific structural or functional descriptions are merely made for the purpose of describing embodiments of the present invention. Embodiments of the present invention may be embodied in various forms, and the present invention should not be construed as being limited to embodiments of the present invention disclosed in the detailed description.

Since the present invention may have diverse modified embodiments, preferred embodiments are illustrated in the drawings and are described in the detailed description of the present invention. However, this does not limit the present invention within specific embodiments and it should be understood that the present invention covers all the modifications, equivalents, and replacements within the idea and technical scope of the present invention. Like reference numerals refer to like elements throughout.

In the following description, the technical terms are used only for explain a specific exemplary embodiment while not limiting the present invention. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

Hereinafter, embodiments of the present invention will be described in detail with reference to the accompanying drawings.

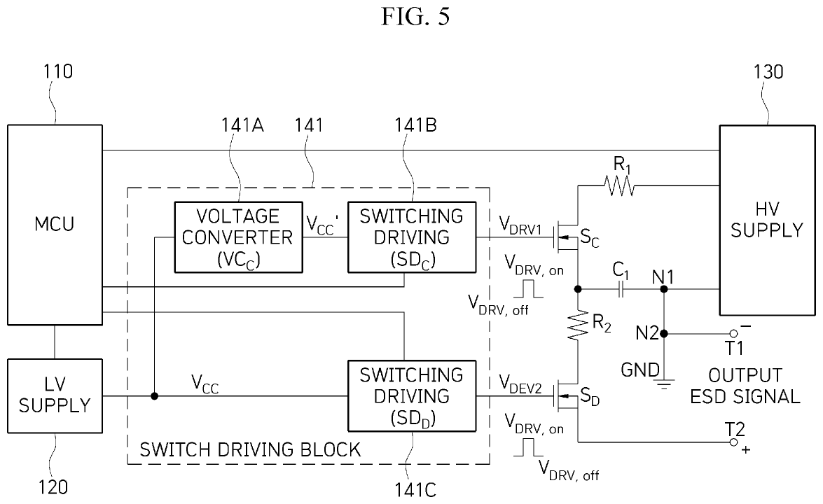

FIG. 4 is a block diagram of an apparatus 100 for ESD test according to an embodiment of the present invention.

Referring to FIG. 4, the apparatus 100 for ESD test according to an embodiment of the present invention may be implemented with one miniaturized semiconductor integrated circuit module which is configured so that a below-described ESD generator 140 does not include a conventional mercury relay.

To this end, the apparatus 100 for ESD test according to an embodiment of the present invention may include a micro-controller unit (MCU) 110, a low voltage (LV) supply 120, a high voltage (HV) supply 130, and an ESD generator 140 implemented with a single semiconductor integrated circuit module.

In a fixed test environment where the apparatus 100 for ESD test tests ESD of a device under test (DUT) of each wafer, the MCU 110 may be installed in a measuring machine (not shown), and the ESD generator 140 may be installed in a probe card connected to the measuring machine.

In the fixed test environment, the MCU 110 may be separated from the

ESD generator 140. In this case, the low voltage supply 120 and the high voltage supply 130 may be installed in the measuring machine.

Unlike the fixed test environment, in a movable test environment for testing ESD of a DUT (or a finished product) such as an electronic/electrical product, the MCU 110, the low voltage supply 120, the high voltage supply 130, and the ESD generator 140 may be installed in one movable test apparatus.

The MCU 110 may be a device where a processor, a memory, and an input/output (I/O) device are implemented as a single chip type and may control and manage operations of the low voltage supply 120, the high voltage supply 130, and the ESD generator 140. For example, the MCU 110 may generate a signal associated with charge/discharge timing control for ESD test and may provide the signal to each of the low voltage supply 120, the high voltage supply 130, and the ESD generator 140.

The low voltage supply 120 may output a low voltage Vcc on the basis of control by the MCU 110, and the high voltage supply 130 may output a high voltage on the basis of control by the MCU 110.

The ESD generator 140 may generate an ESD signal (or an ESD voltage) for an ESD test of a DUT on the basis of control by the MCU 110 and may be implemented with one semiconductor integrated circuit module which is miniaturized not to include a switch such as a conventional mercury relay.

In an embodiment, the ESD generator 140 may include a switch driving block 141, a charging semiconductor switch S_{C}, a discharging semiconductor switch S_{D}, a charging resistor R₁, a discharging resistor R₂, and a charging/discharging capacitor C₁.

The switch driving block 141 may generate switch driving voltages V_{DRV1} and V_{DRV2} for controlling a switching operation (a turn-on and turn-off operation) of the charging semiconductor switch S_{C} and the discharging semiconductor switch S_{D}. For example, the switch driving block 141 may boost or drop the low voltage Vcc input from the low voltage supply 120 to generate the switch driving voltages V_{DRV1} and V_{DRV2}, on the basis of control by the MCU 110.

The switch driving block 141 may be implemented as a non-insulation circuit for enduring a higher voltage than a breakdown voltage of each of two semiconductor switches S_{C} and S_{D} for charging and discharging a high voltage, supplied from the high voltage supply 130, into and from the charging/discharging capacitor C₁.

On the other hand, when the switch driving block 141 does not endure the breakdown voltage of each of the two semiconductor switches S_{C} and S_{D}, the switch driving block 141 may be implemented as an insulation circuit where reference voltages (or source voltages) of the two semiconductor switches S_{C} and S_{D} are separated from each other.

The two semiconductor switches S_{C} and S_{D} for charging and discharging the high voltage, supplied from the high voltage supply 130, into and from the charging/discharging capacitor C₁ may have a higher breakdown voltage characteristic than the high voltage (or a charging voltage charged into the capacitor C₁).

The two semiconductor switches S_{C} and S_{D} turned on based on the switch driving voltages V_{DRV1} and V_{DRV2} from the switch driving block 141 may each be a switching element having a low turn-on voltage and an excellent current slope characteristic, and in this case, the kind thereof is not limited.

For example, the two semiconductor switches S_{C} and S_{D} may each be implemented as a thyristor-based semiconductor device including a MOS controlled (MCT) thyristor, a field effect transistor (FET)-based semiconductor device such as a metal-oxide-semiconductor field effect transistor (MOSFET), or a bipolar junction transistor (BJT)-based semiconductor device such as an insulated gate bipolar transistor (IGBT).

A gate terminal G of the charging semiconductor switch S_{C} may be connected to the switch driving block 141 and may perform a switching operation on the basis of the switch driving voltage V_{DRV1} from the switch driving block 141.

A drain terminal D of the charging semiconductor switch S_{C} may be connected to one terminal of the charging resistor R₁, and the other terminal of the charging resistor R₁ may be connected to a positive (+) terminal 131 of the high voltage supply 130. Accordingly, the drain terminal D of the charging semiconductor switch S_{C} may be connected to the positive (+) terminal 131 of the high voltage supply 130 by the charging resistor R₁.

A source terminal S of the charging semiconductor switch S_{C} may be connected to one terminal of the charging/discharging capacitor C₁, and the other terminal of the charging/discharging capacitor C₁ may be connected to a negative (−) terminal 132 of the high voltage supply 130 by a first node N₁. Accordingly, the source terminal S of the charging semiconductor switch S_{C} may be connected to the negative (−) terminal 132 of the high voltage supply 130 by the charging/discharging capacitor C₁.

Based on a connection structure of the charging semiconductor switch S_{C}, when the charging semiconductor switch S_{C} is turned on based on the switch driving voltage from the switch driving block 141, the high voltage output from the high voltage supply 130 may be charged into the charging/discharging capacitor C₁.

Moreover, the first node N1 between the other electrode of the charging/discharging capacitor C₁ and the negative (−) terminal 132 of the high voltage supply 130 may be connected to a ground GND by a second node N2, and the second node N2 may be connected to a negative (−) output terminal T1 which outputs the ESD signal (or the ESD voltage) applied to a DUT.

The source terminal S of the charging semiconductor switch S_{C} may be connected to one electrode of the charging/discharging capacitor C₁ and one terminal of the charging resistor R₂, and the other terminal of the charging resistor R₂ may be connected to a drain terminal D of the discharging semiconductor switch S_{D}. Accordingly, the source terminal S of the charging semiconductor switch S_{C} may be connected to the drain terminal D of the discharging semiconductor switch S_{D} by the charging resistor R₂.

A gate terminal G of the discharging semiconductor switch S_{D} may be connected to the switch driving block 141 and may perform a switching operation on the basis of the switch driving voltage V_{DRv2} from the switch driving block 141. Also, the source terminal S of the charging semiconductor switch S_{C} may be connected to a positive (+) output terminal T2 which outputs the ESD signal (or the ESD voltage) applied to the DUT.

Based on a connection structure of the discharging semiconductor switch S_{D}, when the discharging semiconductor switch S_{D} is turned on based on the switch driving voltage from the switch driving block 141, the high voltage (a charging voltage) charged into the charging/discharging capacitor C₁ may be output as the ESD signal (or the ESD voltage) through the positive (+) output terminal T2 and the negative (−) output terminal T1.

While the charging semiconductor switch S_{C} is maintaining a turn-on state, the discharging semiconductor switch S_{D} may maintain a turn-off state, but while the charging semiconductor switch S_{C} is maintaining a turn-off state, the discharging semiconductor switch S_{D} may maintain a turn-on state.

FIG. 5 is a block diagram illustrating an example of the switch driving block illustrated in FIG. 4.

Referring to FIG. 5, a switch driving block 141 may be variously designed based on a supply voltage Vcc from a low voltage supply 120 and a switch driving voltage applied to a gate terminal G of each of semiconductor switches S_{C} and S_{D}.

The switch driving block 141 according to an embodiment of the present invention may include a voltage converter 141A, a charging switching driver 141B, and a discharging switching driver 141C.

The voltage converter 141A may convert the supply voltage Vcc from the low voltage supply 120 to output a converted supply voltage Vcc′ to the charging switching driver 141B.

The charging switching driver 141B may generate a switch driving voltage V_{DRV1} corresponding to the converted supply voltage Vcc′ from the voltage converter 141A and may apply the switch driving voltage V_{DRV1} to a gate terminal G of the charging semiconductor switch S_{C}, on the basis of control by an MCU 110.

The discharging switching driver 141C may generate a switch driving voltage V_{DRV2} corresponding to the supply voltage Vcc from the voltage converter 141A and may apply the switch driving voltage V_{DRV2} to a gate terminal G of the discharging semiconductor switch S_{D}, on the basis of control by the MCU 110.

As illustrated in FIG. 5, a switch driving block 141 including one voltage converter 141A disposed between the low voltage supply 120 and the charging switching driver 141B may be used when a supply voltage Vcc supplied from the low voltage supply 120 is the same as a switch driving voltage output from each of two switching drivers 141B and 141C.

For example, when a reference voltage (a source voltage) of the charging semiconductor switch S_{C} is set to be higher than a reference voltage (a source voltage) of the discharging semiconductor switch S_{D}, the voltage converter 141A may boost the supply voltage Vcc supplied from the low voltage supply 120, and the charging switching driver 141B may generate a switch driving voltage corresponding to a boosted supply voltage Vcc′ and may apply the switch driving voltage to a gate terminal of the charging semiconductor switch S_{C}.

The switch driving block 141 illustrated in FIG. 5 may be configured to include two switching drivers 141B and 141C, but based on a design, the switch driving block 141 may be configured to include only one switching driver. For example, the discharging switching driver 141C for controlling a switching operation of the discharging semiconductor switch S_{D} may be removed. In this case, the MCU 110 may generate the switch driving voltage to control a switching operation of the discharging switching driver 141C.

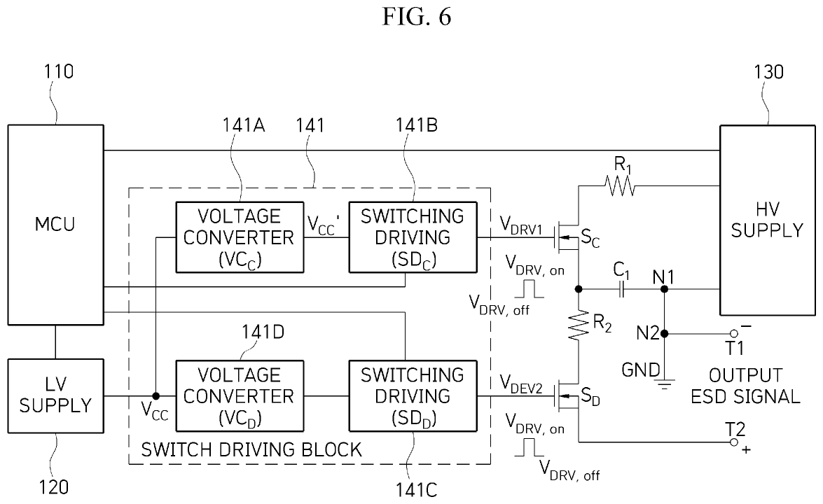

FIG. 6 is a block diagram illustrating another example of the switch driving block illustrated in FIG. 4.

Referring to FIG. 6, a switch driving block 141 according to another embodiment of the present invention may have a difference with the embodiment of FIG. 5 in that a voltage converter 141D is further provided between a low voltage supply 120 and a discharging switching driver 141C.

The switch driving block 141 according to another embodiment of the present invention may be used when a supply voltage Vcc supplied from the low voltage supply 120 differs from a switch driving voltage output from each of two switching drivers 141B and 141C.

For example, when the supply voltage Vcc supplied from the low voltage supply 120 is higher than the switch driving voltage output from each of two switching drivers 141B and 141C, each of voltage converters 141A and 141D may be a step-down voltage converter which drops the supply voltage Vcc.

On the other hand, when the supply voltage Vcc supplied from the low voltage supply 120 is lower than the switch driving voltage output from each of the two switching drivers 141B and 141C, each of voltage converters 141A and 141D may be a step-up voltage converter which boosts the supply voltage Vcc.

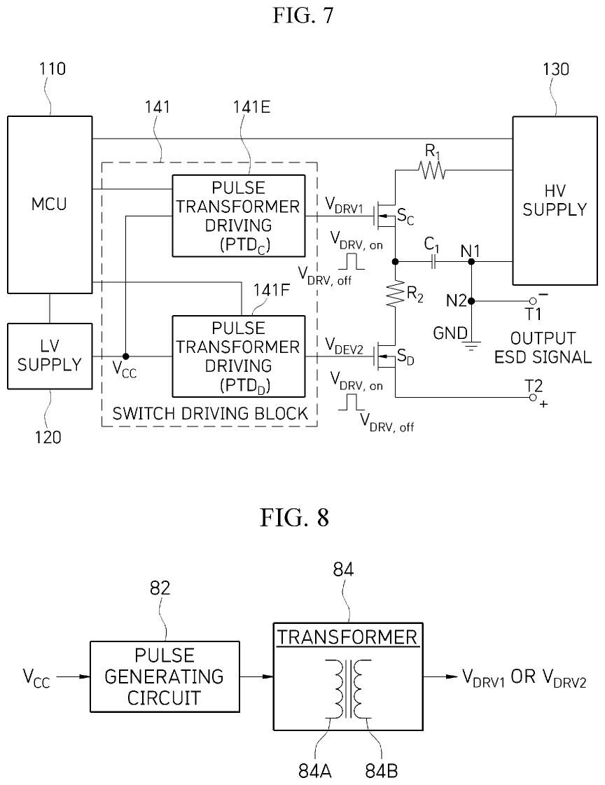

FIG. 7 is a block diagram illustrating another example of the switch driving block illustrated in FIG. 4, and FIG. 8 is a block diagram illustrating an example of a pulse transformer driver illustrated in FIG. 7.

Referring to FIG. 7, a switch driving block 141 according to another embodiment of the present invention may have a difference with the embodiments of FIGS. 5 and 6 in that the charging switching driver 141B and the discharging switching driver 141C illustrated in FIGS. 5 and 6 are respectively replaced with a pulse transformer driver 141E for charging and a pulse transformer driver 141F for discharging.

Moreover, in a case where the switching drivers 141B and 14C are replaced with the pulse transformer drivers 141E and 141F, the voltage converters 141A and 141D illustrated in FIGS. 5 and 6 may not need a design.

In the switch driving block 141 according to another embodiment of the present invention, two pulse transformer drivers may be independently designed regardless of whether a supply voltage Vcc is the same as or different from a switching driving voltage.

Each of the pulse transformer drivers, as illustrated in FIG. 8, may include a pulse generating circuit 82 and a transformer 84.

The pulse generating circuit 82 may generate a pulse voltage corresponding to the supply voltage Vcc from the low voltage supply 120, and the transformer 84 may include a primary coil 84A and a secondary coil electromagnetically coupled to the primary coil 84A, in order to convert the pulse voltage from the pulse generating circuit 82 to generate the switching driving voltage.

The transformer 84 may boost or drop the pulse voltage from the pulse generating circuit 82 to generate switching driving voltages V_{DRV1} and V_{DRV2}, on the basis of a turn ratio. In this case, a turn ratio between the primary coil and the secondary coil may be determined based on a ratio of the supply voltage Vcc to the switching driving voltage V_{DRV1} or V_{DRV2}.

According to the embodiments of the present invention, in implementing an ESD generator which generates a current waveform for ESD test, a conventional mercury relay designed in the ESD generator may be replaced with a semiconductor integrated circuit module which provides an excellent current slope characteristic, and thus, an environmental pollution problem caused by designing of a mercury relay may be solved.

Moreover, the ESD generator may be implemented with a miniaturized semiconductor integrated circuit module and may be equipped in a semiconductor probe card, and thus, an ESD test time of a semiconductor wafer may be reduced, thereby largely decreasing a total semiconductor manufacturing time.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An apparatus for electrostatic discharge (ESD) test, the apparatus comprising:
a micro-controller unit client;
a low voltage supply configured to output a low voltage on the basis of control by the micro-controller unit;
a high voltage supply configured to output a high voltage on the basis of control by the micro-controller unit; and
an ESD generator configured to generate an ESD voltage for an ESD test of a device under test (DUT) by using the low voltage and the high voltage, on the basis of control by the micro-controller unit,
wherein the ESD generator is a semiconductor integrated circuit module where a charging semiconductor switch, a discharging semiconductor switch, a switch driving block controlling a switching operation of each of the charging semiconductor switch and the discharging semiconductor switch, and a plurality of passive elements connected to the charging semiconductor switch and the discharging semiconductor switch are implemented as package, for generating the ESD voltage.

2. The apparatus of claim 1, wherein each of the charging semiconductor switch and the discharging semiconductor switch is a semiconductor switch replacing a mercury relay switch included in a conventional ESD generator.

3. The apparatus of claim 1, wherein each of the charging semiconductor switch and the discharging semiconductor switch is one of a thyristor-based semiconductor device including a MOS controlled (MCT) thyristor, a field effect transistor (FET)-based semiconductor device, an insulated gate bipolar transistor (IGBT)-based semiconductor device, and a bipolar junction transistor (BJT)-based semiconductor device.

4. The apparatus of claim 1, wherein the switch driving block outputs a first switching driving voltage for controlling a switching operation of the charging semiconductor switch and a second switching driving voltage for controlling a switching operation of the discharging semiconductor switch, by using the low voltage.

5. The apparatus of claim 4, wherein the switch driving block comprises:
a voltage converter configured to boost or drop the low voltage;
a charging switching driver configured to output the first switching driving voltage corresponding to the boosted or dropped low voltage on the basis of control by the micro-controller unit;
a discharging switching driver configured to output the second switching driving voltage corresponding to the low voltage on the basis of control by the micro-controller unit.

6. The apparatus of claim 5, wherein the first and second switching driving voltages have the same voltage level as a voltage level of the low voltage.

7. The apparatus of claim 4, wherein
the switch driving block comprises:
a voltage converter configured to boost or drop the low voltage; and
a charging switching driver configured to output the first switching driving voltage corresponding to the boosted or dropped low voltage on the basis of control by the micro-controller unit, and
the discharging semiconductor switch performs a switching operation on the basis of the second switching driving voltage output from the micro-controller unit.

8. The apparatus of claim 4, further comprising:
a first voltage converter configured to boost or drop the low voltage;
a charging switching driver configured to output the first switching driving voltage corresponding to a low voltage boosted or dropped by the first voltage converter on the basis of control by the micro-controller unit;
a second voltage converter configured to boost or drop the low voltage; and
a discharging switching driver configured to output the second switching driving voltage corresponding to a low voltage boosted or dropped by the second voltage converter on the basis of control by the micro-controller unit.

9. The apparatus of claim 8, wherein the first and second switching driving voltages have a voltage level which differs from a voltage level of the low voltage.

10. The apparatus of claim 1, wherein the plurality of passive elements comprise:
a charging resistor including one terminal connected to a drain terminal of the charging semiconductor switch and the other terminal connected to a positive terminal of the high voltage supply;
a charging/discharging capacitor including one electrode connected to a source terminal of the charging semiconductor switch and the other electrode connected to a negative terminal of the high voltage supply; and
a discharging resistor connecting a source terminal of the charging semiconductor switch to a drain terminal of the discharging semiconductor switch.

11. The apparatus of claim 10, wherein,
when a first node connecting a ground to the other electrode of the charging/discharging capacitor and the negative terminal of the high voltage supply and a second node connecting the first node to the ground are defined,
a high voltage output from the high voltage supply is charged into the charging/discharging capacitor via the charging resistor and the turned-on charging semiconductor switch, and
a charging voltage charged into the charging/discharging capacitor is output as the ESD voltage via the discharging resistor and the turned-on discharging semiconductor switch.

12. The apparatus of claim 11, wherein the charging semiconductor switch and the discharging semiconductor switch have a breakdown voltage characteristic which is higher than the charging voltage.

13. An apparatus for electrostatic discharge (ESD) test, the apparatus comprising:
a charging pulse transformer driver configured to convert a low voltage to generate a first switching driving voltage;
a discharging pulse transformer driver configured to convert the low voltage to generate a second switching driving voltage;
a charging semiconductor switch configured to perform a switching operation on the basis of the first switching driving voltage;
a discharging semiconductor switch configured to perform a switching operation on the basis of the second switching driving voltage; and
a capacitor configured to store a high voltage on the basis of a switching operation of the charging semiconductor switch and to output the stored high voltage as an ESD voltage for an ESD test of a device under test (DUT) on the basis of a switching operation of the discharging semiconductor switch.

14. The apparatus of claim 13, wherein the charging pulse transformer driver, the discharging pulse transformer driver, the charging semiconductor switch, and the discharging semiconductor switch are packaged by one semiconductor integrated circuit module.

15. The apparatus of claim 13, wherein each of the charging pulse transformer driver and the discharging pulse transformer driver comprises:
a pulse generating circuit configured to generate a pulse voltage corresponding to the low voltage; and
a transformer including a primary coil configured to convert the pulse voltage to generate a switching driving voltage and a secondary coil electromagnetically coupled to the primary coil.

16. The apparatus of claim 15, wherein a turn ratio between the primary coil and the secondary coil is determined based on a ratio of the low voltage to the switching driving voltage.
